(19) United States
(12) Patent Application Publication
(10) Pub. No.: US 2016/0033882 A1
(43) Pub. Date: Feb. 4, 2016

(54) METHODS AND APPARATUS FOR SUBSTRATE SUPPORT ALIGNMENT

(71) Applicant: Applied Materials, Inc., Santa Clara, CA (US)

(72) Inventor: JADHAV DEEPAK, Hubli (IN)

(21) Appl. No.: 14/505,207

(22) Filed: Oct. 2, 2014

Related U.S. Application Data
(60) Provisional application No. 62/032,566, filed on Aug. 2, 2014.

(51) Int. Cl. G03F 7/20

(52) U.S. Cl. CPC G03F 7/70775

(57) ABSTRACT

Methods and apparatus for aligning a substrate support are provided herein. In some embodiments, a method of aligning a substrate support includes: measuring a tilt of a substrate support along a direction using a tilt sensor disposed on the substrate support; and determining whether the measured tilt of the substrate support in the direction is less than or equal to a predefined value. In some embodiments, a substrate support alignment system includes: a tilt sensor; and a holding element that holds the tilt sensor and which is locatable on a support surface of a substrate support to locate the tilt sensors in a predetermined orientation with respect to the support surface.

### CROSS-REFERENCE TO RELATED APPLICATIONS

This application claims benefit of U.S. provisional patent application Ser. No. 62/032,566, filed Aug. 2, 2014, which is herein incorporated by reference in its entirety.

### FIELD

Embodiments of the present disclosure generally relate to a substrate support in a processing system and, more particularly, to aligning a substrate support in a chamber of a processing system.

### BACKGROUND

The alignment of a substrate support within the chamber of a processing system can seriously affect the outcome of a process. For example, in the semiconductor industry, the correct alignment of a substrate support for supporting a semiconductor wafer or other substrate within a process chamber has become a major issue because its misalignment can adversely affect various process parameters. As an example, misalignment of the tilt of the substrate support with respect to a reference plane may cause drift in process parameters. The misalignment of the substrate support can also cause non-uniformity in process outcomes from wafer to wafer. Further, the misalignment between the substrate supports of two or more process chambers can cause inconsistencies in the process results between such chambers.

However, the inventor has observed that no reliable product or gauge exists that can properly align the substrate support. Present methods may align the pedestal using a dial gauge fixture to align the substrate support to the chamber body. These methods are usually very time consuming and cause personnel to spend a great deal of time in aligning the substrate support. Also, alignment of the substrate support is only possible with respect to a chamber body. Chamber to chamber substrate support alignment with respect to a common reference plane is not possible.

Accordingly, a method and apparatus for aligning a substrate support within a process chamber is disclosed.

### SUMMARY

Methods and apparatus for aligning a substrate support are provided herein. In some embodiments, a method of aligning a substrate support includes: measuring a tilt of a substrate support along a direction using a tilt sensor disposed on the substrate support; and determining whether the measured tilt of the substrate support in the direction is less than or equal to a predefined value.

In some embodiments, a method of aligning a substrate support in a processing system includes: inserting a substrate support into a processing system; placing two or more tilt sensors on the substrate support; measuring, using the two or more tilt sensors, a degree of tilt of the substrate support along two or more directions; and determining whether the measured degree of tilt of the substrate support along the two or more directions is less than or equal to corresponding predefined values.

In some embodiments, a substrate support alignment system includes: a tilt sensor; and a holding element that holds the tilt sensor and which is locatable on a support surface of a substrate support to locate the tilt sensors in a predetermined orientation with respect to the support surface.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. It is to be noted, however, that the appended drawings illustrate only typical embodiments of this disclosure and are therefore not to be considered limiting of its scope, for the disclosure may admit to other equally effective embodiments.

FIG. 1 is a diagram illustrating an alignment gauge in accordance with some embodiments of the present disclosure.

FIG. 2 is a diagram illustrating a system which incorporates an alignment gauge in accordance with some embodiments of the present disclosure.

FIG. 3 is a diagram illustrating an example of a process chamber and substrate support in which an alignment gauge in accordance with some embodiments of the present disclosure is used.

FIG. 4 is a flowchart showing an example of a method of aligning a substrate support in accordance with some embodiments of the present disclosure.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present disclosure provides methods and apparatus to align a substrate support in a process chamber. The inventive methods and apparatus use tilt sensors to measure the position of the substrate support, for example, with respect to a reference plane. The tilt sensors may be mounted on a ring which serves as an alignment gauge. In some embodiments, the tilt sensors may be an accelerometer, such as a micro-electromechanical system (MEMS) accelerometer or the like. The alignment gauge is placed on a substrate support inside a process chamber of a processing system, either on a substrate surface or the substrate support or on a surface surrounding the substrate surface. The alignment gauge measures tilt data with respect to a reference plane, such as a plane aligned to the chamber body, a plane tangential to the surface of the earth, or some other calibrated plane. The measured tilt data is displayed and may be read while a user corrects the substrate support alignment until the displayed tilt data indicates that the substrate support is aligned with the reference plane.

Accelerometers, such as MEMS accelerometers, can measure acceleration resulting from movement of the accelerometer or can measure static acceleration caused by gravity. Conceptually, an accelerometer consists of a proof mass and restoring springs and behaves as a damped mass on a spring. When the accelerometer experiences an acceleration, the proof mass experiences a force (F=ma) and is displaced in proportion to the force. The displacement is measured to determine the acceleration. For example, the displacement of the proof mass may cause a change in the capacitance between two sensing plates within the accelerometer, and the change in capacitance is used to measure the movement of the proof mass and hence the acceleration. Because the movement of the proof mass is not linear, a sine wave is outputted by the accelerometer which can be used to calculate a linear acceleration. A tilt angle of the substrate support can then be determined using the calculated static acceleration caused by gravity.

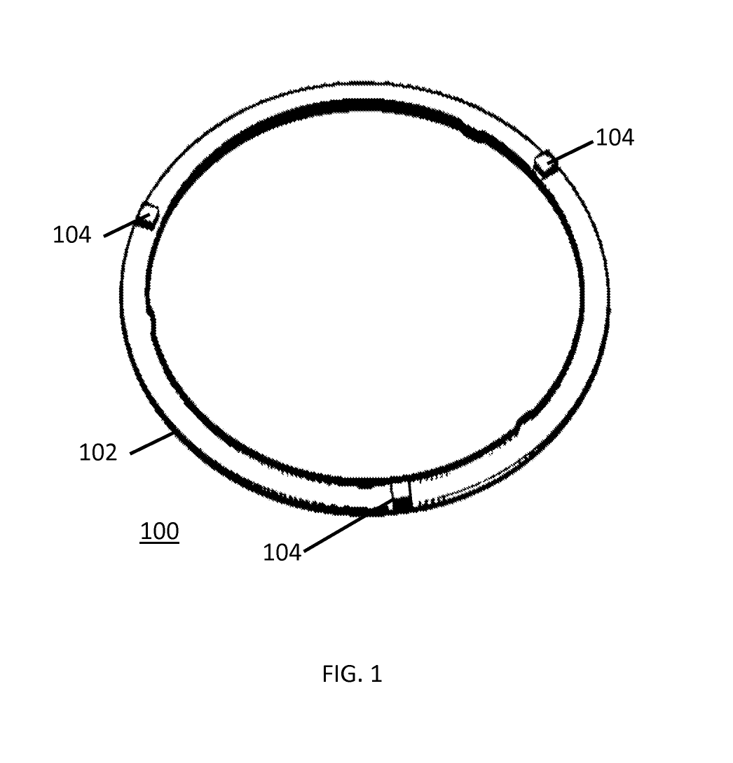

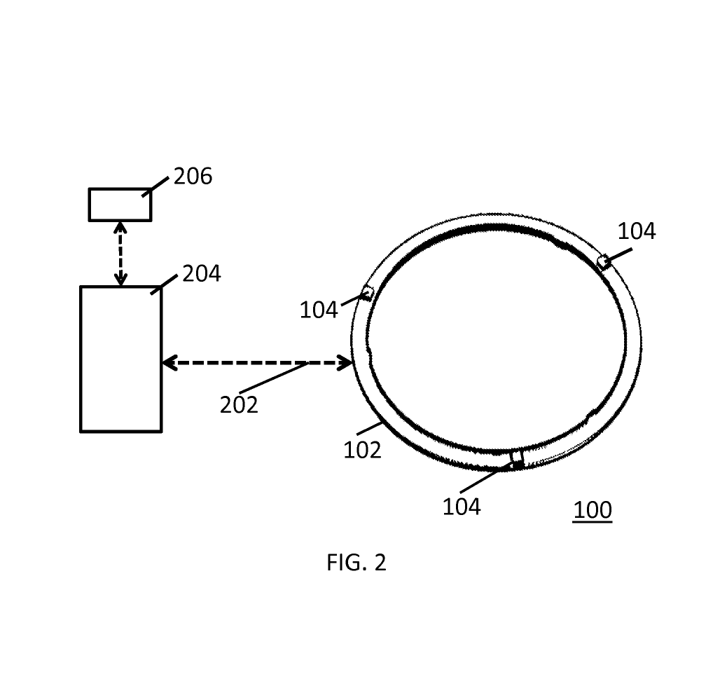

FIG. 1 shows an alignment gauge 100 in accordance with some embodiments of the present disclosure. A holding element 102, such as a ring as shown in FIG. 1, supports one or more tilt sensors 104. Additional circuitry (for example, as described below with respect to FIG. 2) may be provided to read and/or store tilt data measured by the one or more tilt sensors 104.

The holding element 102 is locatable on a support surface of a substrate support to locate the one or more tilt sensors in a predetermined orientation with respect to the support surface. In some embodiments, the predetermined orientation is parallel to a plane containing the support surface. For example, the holding element 102 includes a first side configured to interface with the support surface of the substrate support to be aligned. The one or more tilt sensors may be disposed, for example, on a second side of the holding element 102, opposite the first side. Although the holding element 102 is shown as a ring in FIG. 1, other configurations may be used as well. For example, the holding element may be a disc, rectangle, or other shape suitable to be disposed on a support surface of a substrate support in a predetermined orientation. In some embodiments, the alignment gauge may be a planar member, such as a flat disc, ring, or other planar shape.

The alignment gauge 100 may be calibrated with respect to a flat reference plane. The reference plane can be a plane of a chamber in which the substrate support is located, a plane tangential to the surface of the earth, or a plane calibrated to the plane tangential to the surface of the earth. As such, the holding element is configured to interface with the substrate support in a predetermined orientation, such that the tilt sensors can measure tilt data corresponding to the orientation of the substrate support with respect to the reference plane.

The holding element 102 may be configured to interface with (e.g., rest upon) a substrate support in a plane parallel to a plane of a support surface of the substrate support. As such, the holding element 102 may be used to align the plane of the support surface of the substrate support to the reference plane. As used herein, the support surface of the substrate support refers to the surface upon which a substrate rests or is supported during use.

The one or more tilt sensors may be any devices suitable for measuring the tilt of a substrate support, such as accelerometers, for example, MEMS accelerometers. In some embodiments, the alignment gauge 100 has two tilt sensors, and a degree of tilt of the substrate support may be measured in two directions when the alignment gauge is disposed on the support surface. In some embodiments, the alignment gauge 100 has three tilt sensors, and a degree of tilt of the substrate support may be measured in three directions when the alignment gauge is disposed on the support surface. In some embodiments, each tilt sensor is spaced an equal distance on the ring from adjacent tilt sensors.

FIG. 2 shows a substrate support alignment system 200 in accordance with some embodiments of the present disclosure that, for example, uses the alignment gauge 100 of FIG. 1. The tilt data measured by the alignment gauge 100 is transmitted over a network 202 to a remote device 204. The network 202 may be a wired or wireless network, such as a Bluetooth network or other local area network. The remote device 204 may be any suitable device for receiving and displaying the measured tilt data, for example, a computer (such as a personal computer or other computer), a smartphone or other handheld device, or the like. The remote device 204 includes a display 206 which can display the measured tilt data using, for example, display software that allows for a two-dimensional or three-dimensional depiction of the substrate support and its alignment to a representation of a reference plane and which may show the changes in the tilt of the substrate support as it is brought into alignment with the reference plane. Alternatively, the measured tilt data may be displayed using numeric or other data.

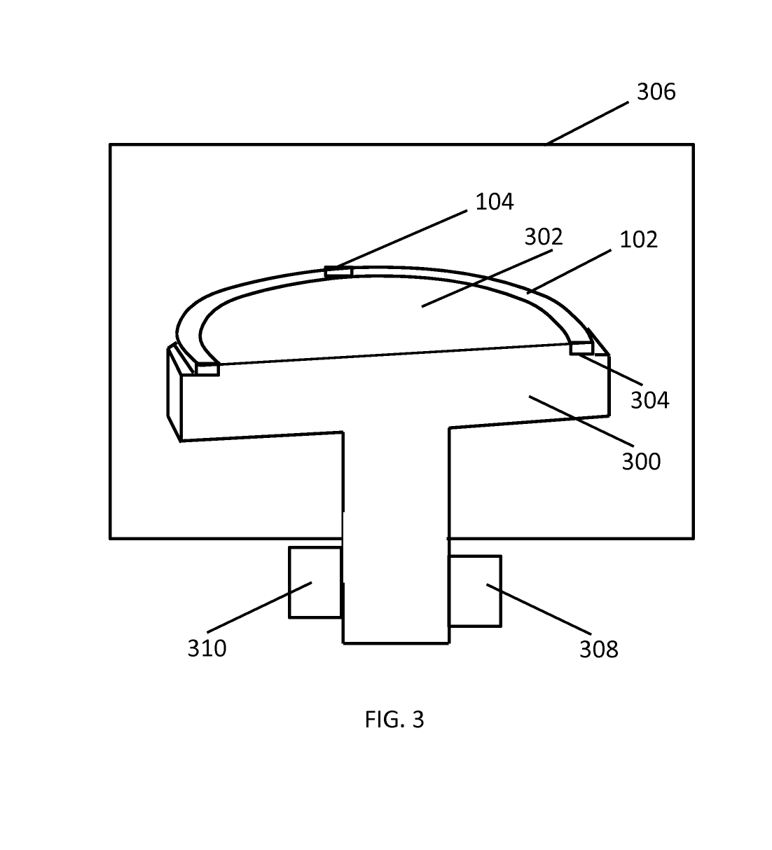

FIG. 3 shows an example of substrate support 300 which is inserted inside a process chamber 306 of a processing system and upon which the alignment gauge 100 is placed to determine the alignment of the substrate support 300 with respect to the reference plane. The alignment gauge 100 may be disposed atop a support surface 302 of the substrate support 300 or, as shown, may be disposed atop a ledge 304 that is adjacent to the support surface 302 of the substrate support 300. An adjustment mechanism 308 is provided to adjust the tilt of the support surface 302. For example, jack bolts may be disposed about the substrate support 300 or about the support surface 302 to adjust the tilt of the support surface 302 by adjustment of the jack bolts. Alternatively or in combination, a locking mechanism 310 may be provided to secure the support surface 302 in the desired position after checking, and optionally adjusting, the position or orientation of the support surface 302 with respect to the reference plane with the alignment gauge 100.

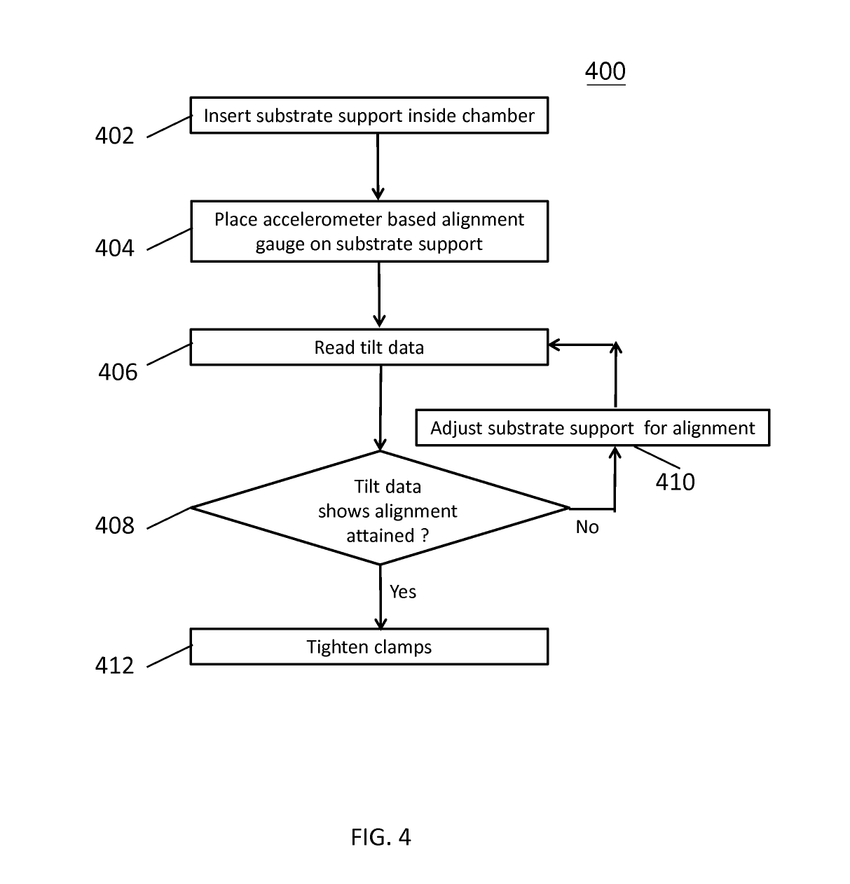

FIG. 4 is a flowchart showing a method 400 of aligning a substrate support in accordance with some embodiments of the present disclosure. The method 400 generally begins at 402, where a substrate support, such as the substrate support 300 shown in FIG. 3, is installed inside a process chamber of a processing system. At 404, an alignment gauge, such as the alignment gauge 100 shown in FIGS. 1-3, is placed on the substrate support. The alignment gauge may be placed on the substrate support before or after installation in the process chamber. Next, at 406, tilt data measured by the alignment gauge is read from a display, such as in the manner described above. At 408, it is determined whether alignment is achieved (e.g., if the substrate support is or is not aligned to within a desired tolerance of the reference plane). If alignment is not achieved, then at 410, the substrate support is adjusted to be brought closer to alignment in response to the tilt data provided by the alignment gauge. 406, 408, and 410 may be repeated until the substrate support is satisfactorily aligned. If necessary, once the substrate support is aligned, then at 412, the substrate support may be clamped in place or otherwise secured (for example using clamps, bolts, or the like) to retain the substrate support at the proper tilt.

While the foregoing is directed to embodiments of the present disclosure, other and further embodiments of the disclosure may be devised without departing from the basic scope thereof.

1. A method of aligning a substrate support, comprising:
measuring a tilt of a substrate support along a direction using a tilt sensor disposed on the substrate support; and
determining whether the measured tilt of the substrate support in the direction is less than or equal to a predefined value.

2. The method of claim 1, further comprising:
adjusting the substrate support until the tilt of the substrate support in the direction is measured less than or equal to the predefined value.

3. The method of claim 1, wherein the tilt sensor comprises an accelerometer.

4. The method of claim 1, wherein measuring the tilt of the substrate support measures a degree of tilt with respect to a reference plane.

5. The method of claim 4, wherein the reference plane is one of a plane of a chamber in which the substrate support is located, a plane tangential to the surface of the earth, or a plane calibrated to the plane tangential to the surface of the earth.

6. The method of claim 1, further comprising:
placing the tilt sensor onto a support surface of the substrate support or onto a ledge adjoining the support surface.

7. The method of claim 1, wherein the tilt sensor is disposed on a ring or on a substrate configured to locate the tilt sensor in a predetermined orientation with respect to a support surface of the substrate support.

8. The method of claim 1, wherein the tilt sensor comprises three tilt sensors each spaced an equal distance from adjacent tilt sensors.

9. The method of claim 1, further comprising:
transmitting measurement data taken by the tilt sensor to a remote device.

10. The method of claim 9, further comprising:
displaying the transmitted measurement data on a display of the remote device.

11. The method of claim 10, further comprising:
adjusting the substrate support until the displayed measurement data indicates that the tilt of the substrate support in the direction is less than or equal to the predefined value.

12. The method of claim 9, wherein the remote devise is at least one of a smartphone or a computer.

13. A method of aligning a substrate support in a processing system, comprising:
inserting a substrate support into a processing system;
placing two or more tilt sensors on the substrate support;
measuring, using the two or more tilt sensors, a degree of tilt of the substrate support along two or more directions; and
determining whether the measured degree of tilt of the substrate support along the two or more directions is less than or equal to corresponding predefined values.

14. The method of claim 13, further comprising:
adjusting the substrate support until the measured degree of tilt of the substrate support along the two or more directions is less than or equal to the corresponding predefined values.

15. A substrate support alignment system, comprising:
a tilt sensor; and
a holding element that holds the tilt sensor and which is locatable on a support surface of a substrate support to locate the tilt sensors in a predetermined orientation with respect to the support surface.

16. The substrate support alignment system of claim 15, wherein the tilt sensor is an accelerometer.

17. The substrate support alignment system of claim 16, wherein the accelerometer is a micro-electromechanical system (MEMS) accelerometer.

18. The substrate support alignment system of claim 15, further comprising:
an adjustment mechanism that adjusts a position of the substrate support.

19. The substrate support alignment system of claim 15, wherein the holding element is one of a ring that supports the tilt sensor or a substrate that includes the tilt sensor.

20. The substrate support alignment system of claim 15, wherein the holding element is a ring that supports three tilt sensors each spaced equal distances on the ring from its adjacent tilt sensors.
